(19) United States
(12) Patent Application Publication
(10) Pub. No.: US 2014/0084371 A1
(43) Pub. Date: Mar. 27, 2014

(54) MULTI-GATE FIELD EFFECT TRANSISTOR DEVICES

(71) Applicants: Veeraraghavan S. Basker, Schenectady, NY (US); Tenko Yamashita, Schenectady, NY (US); Chun-Chen Yeh, Clifton Park, NY (US)

(72) Inventors: Veeraraghavan S. Basker, Schenectady, NY (US); Tenko Yamashita, Schenectady, NY (US); Chun-Chen Yeh, Clifton Park, NY (US)

(73) Assignee: INTERNATIONAL BUSINESS MACHINES CORPORATION, Armonk, NY (US)

(21) Appl. No.: 13/659,076

(22) Filed: Oct. 24, 2012

Related U.S. Application Data
(63) Continuation of application No. 13/628,251, filed on Sep. 27, 2012.

(51) Int. Cl. H01L 29/78

(52) U.S. Cl. 257/347; 257/E29.255

(57) ABSTRACT

A field effect transistor device includes a substrate, a substrate insulator layer arranged on the substrate, a semiconductor fin arranged on the substrate insulator layer, a source region arranged on a portion of the substrate insulator layer, a drain region arranged on a portion of the substrate insulator layer, a first insulator layer portion arranged on the source region, a second insulator layer portion arranged on the drain region, a gate stack arranged about a channel region of the semiconductor fin, and an insulator portion arranged on the gate stack, wherein the insulator portion arranged on the gate stack is disposed between the first insulator layer portion and the second insulator layer portion.

### CROSS-REFERENCE TO RELATED APPLICATIONS

This is a continuation application of and claims priority from U.S. application Ser. No. 13/628,251, filed on Sep. 27, 2012, the entire contents of which are incorporated herein by reference.

### FIELD OF INVENTION

The present invention relates generally to field effect transistor devices, and more specifically, to multi-gate field effect transistor devices.

### DESCRIPTION OF RELATED ART

Multi-gate field effect transistor (FET) devices include multi-sided channel regions arranged on an insulator layer of a substrate. The channel region and the source and drain regions of the device may be defined by a fin arranged on the substrate. The channel region of the fin is defined by a gate stack arranged conformally over the fin. A dielectric capping layer is formed over the source, drain, and gate stack of the device. Conductive vias are formed as cavities in the capping layer that are filled with a conductive material.

As the size of FET devices is decreased, the distance between the conductive vias and the gate stack is reduced. The reduction in this distance may result in an undesirable parasitic capacitance in the FET device.

### BRIEF SUMMARY

According to one embodiment of the present invention, a field effect transistor device includes a substrate, a substrate insulator layer arranged on the substrate, a semiconductor fin arranged on the substrate insulator layer, a source region arranged on a portion of the substrate insulator layer, a drain region arranged on a portion of the substrate insulator layer, a first insulator layer portion arranged on the source region, a second insulator layer portion arranged on the drain region, a gate stack arranged about a channel region of the semiconductor fin, and an insulator portion arranged on the gate stack, wherein the insulator portion arranged on the gate stack is disposed between the first insulator layer portion and the second insulator layer portion.

According to another embodiment of the present invention, a field effect transistor device includes a substrate, a substrate insulator layer arranged on the substrate, a semiconductor fin arranged on the substrate insulator layer, a source region arranged on a portion of the substrate insulator layer, a drain region arranged on a portion of the substrate insulator layer, a gate stack arranged about a channel region of the semiconductor fin, wherein the gate stack fills a cavity partially defined by a portion of the fin and the substrate insulator layer, and an insulator portion arranged on the gate stack, wherein the insulator portion arranged on the gate stack is disposed between the first insulator layer portion and the second insulator layer portion.

According to yet another embodiment of the present invention, a field effect transistor device includes a substrate, a substrate insulator layer arranged on the substrate, a semiconductor fin arranged on the substrate insulator layer, a source region arranged on a portion of the substrate insulator layer, a drain region arranged on a portion of the substrate insulator layer, a first insulator layer portion arranged on the source region, second insulator layer portion arranged on the drain region, a gate stack arranged about a channel region of the semiconductor fin, an insulator portion arranged on the gate stack, wherein the insulator portion arranged on the gate stack is disposed between the first insulator layer portion and the second insulator layer portion, a first spacer arranged adjacent to a first sidewall of the gate stack and the insulator portion, and a second spacer arranged adjacent to a second sidewall of the gate stack and the insulator portion.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a side view of a substrate.

FIG. 2 illustrates a top view of FIG. 1.

FIG. 3 illustrates a side view of the resultant structure following an epitaxial growth process.

FIG. 4 illustrates a top view of FIG. 3.

FIG. 5 illustrates a side view of the resultant structure following the removal of the hardmask layer.

FIG. 6 illustrates a top view of FIG. 5.

FIG. 7 illustrates a side view of the resultant structure following the removal of the dummy gate stack.

FIG. 8 illustrates a top view of FIG. 7.

FIG. 9 illustrates a side view of the resultant structure following the removal of the exposed portions of the hardmask layer.

FIG. 10 illustrates a top view of FIG. 9.

FIG. 11 illustrates a side view of the resultant structure following the deposition of a dielectric layer.

FIG. 12 illustrates a top view of FIG. 11.

FIG. 13 illustrates a side view of the resultant structure following the deposition of a gate conductor portion.

FIG. 14A illustrates a top view of FIG. 13.

FIG. 14B illustrates a cut away view of the structure along the line 14B of

FIG. 14A.

FIG. 15 illustrates a side view of the resultant structure following the removal of a portion of the gate conductor portion.

FIG. 16 illustrates a top view of FIG. 15.

FIG. 17 illustrates a side view of the resultant structure following the deposition of an insulator portion.

FIG. 18 illustrates a top view of FIG. 17.

FIG. 19 illustrates a top view of the resultant structure following the formation of conductive vias.

FIG. 20 illustrates a cut away view along the line 20 of FIG. 19.

FIG. 21 illustrates a cut away view along the line 21 of FIG. 19.

### DETAILED DESCRIPTION

The methods and resultant structures described herein include a multi-gate device that offers a reduction in parasitic capacitance by increasing the distance between the conductive vias connected to the source and drain region and the gate stack, while allowing the size of the FET device to be reduced.

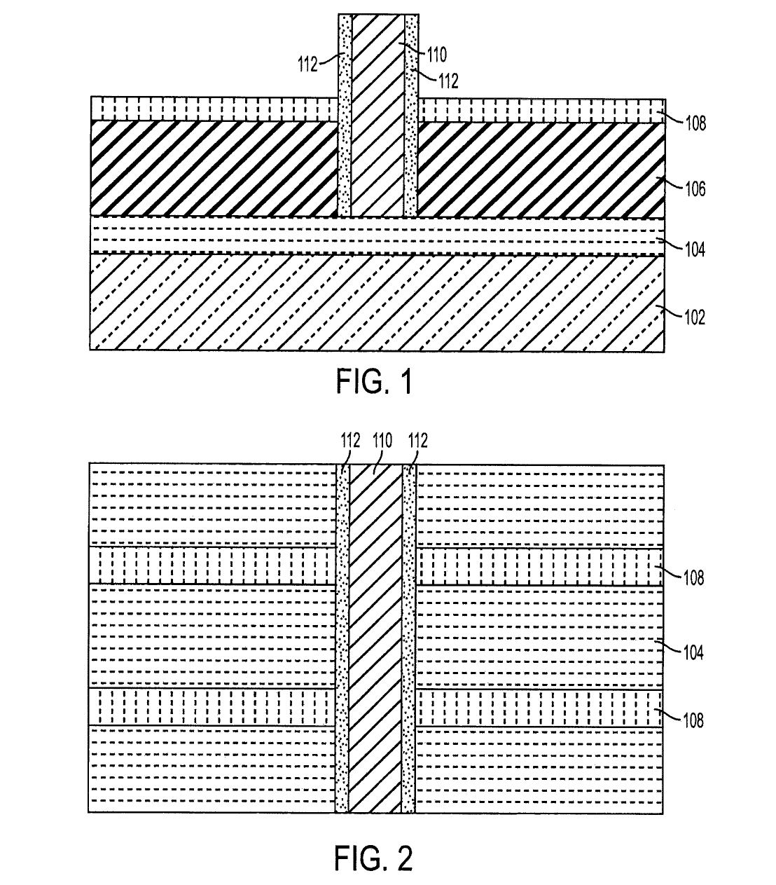

FIG. 1 illustrates a side view of a substrate 102 having a substrate insulator layer 104 disposed thereon. FIG. 2 illustrates a top view of FIG. 1. The substrate may include, for example, a silicon material, and the substrate insulator layer 104 may include a buried oxide (BOX) material. A fin 106 is patterned on a portion of the substrate insulator layer 104. The fin 106 may include a semiconductor material such as a silicon or germanium material. A hardmask layer 108 is arranged on the fin 106, the hardmask layer may include, for example, an oxide material. A dummy gate stack 110 is arranged over a portion of the fin 106. The dummy gate stack 110 may include, for example, a polysilicon material. Spacers 112 are arranged adjacent to the dummy gate stack 110 over portions of the substrate insulator layer 104, and conformally over the fin 106 and hardmask layer 108. The spacers 112 may include, for example, an oxide or nitride material.

The arrangement of FIGS. 1 and 2 may be fabricated using any suitable fabrication processes. For example, the fin 106 and hardmask layer 108 may be formed by depositing the hardmask layer 108 over the semiconductor-on-insulator (SOI) substrate. A photolithographic patterning and etching process is performed to pattern the fin 106 and hardmask layer 108 by pattering a photolithographic mask (not shown) over portions of the hardmask layer 108 and performing an etching process such as a reactive ion etching (RIE) process that removes exposed portions of the hardmask layer and the SOI layer to pattern the fin 106 and expose portions of the substrate insulator layer 104. The dummy gate stack 110 may be formed by depositing a layer of dummy gate stack material conformally over the exposed portions of the substrate insulator layer 104, the fin 106, and the hardmask layer 108. A patterning and etching process such as RIE may be performed to pattern the dummy gate stack 110. The spacers 112 may be formed by depositing a conformal layer of spacer material and performing an anisotropic etching process to define the spacers 112.

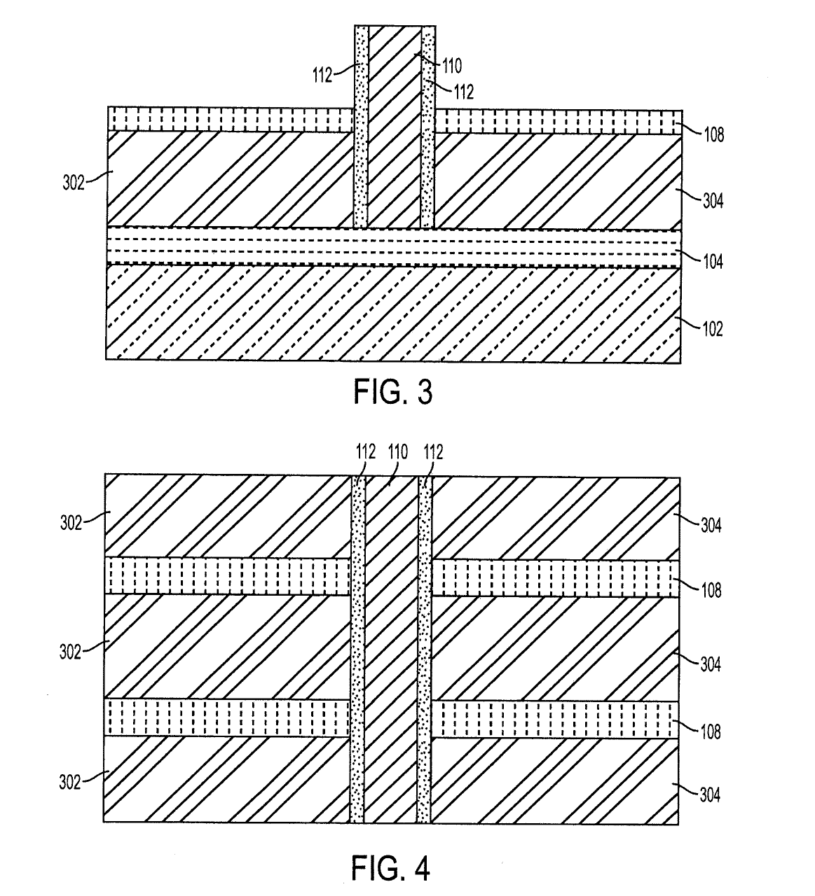

FIG. 3 illustrates a side view, and FIG. 4 illustrates a top view of the resultant structure following an epitaxial growth process that forms source and drain regions 302 and 304 respectively. The epitaxial growth process grows an epitaxial material such as an epi-silicon or an epi-germanium material from exposed sidewalls of the fins 106 (of FIG. 1). Following the growth of the source and drain regions 302 and 304, an ion implantation and annealing process may be performed to dope the source and drain regions 302 and 304. Alternatively, the source and drain regions 302 and 304 may be doped in-situ during the epitaxial growth process if desired.

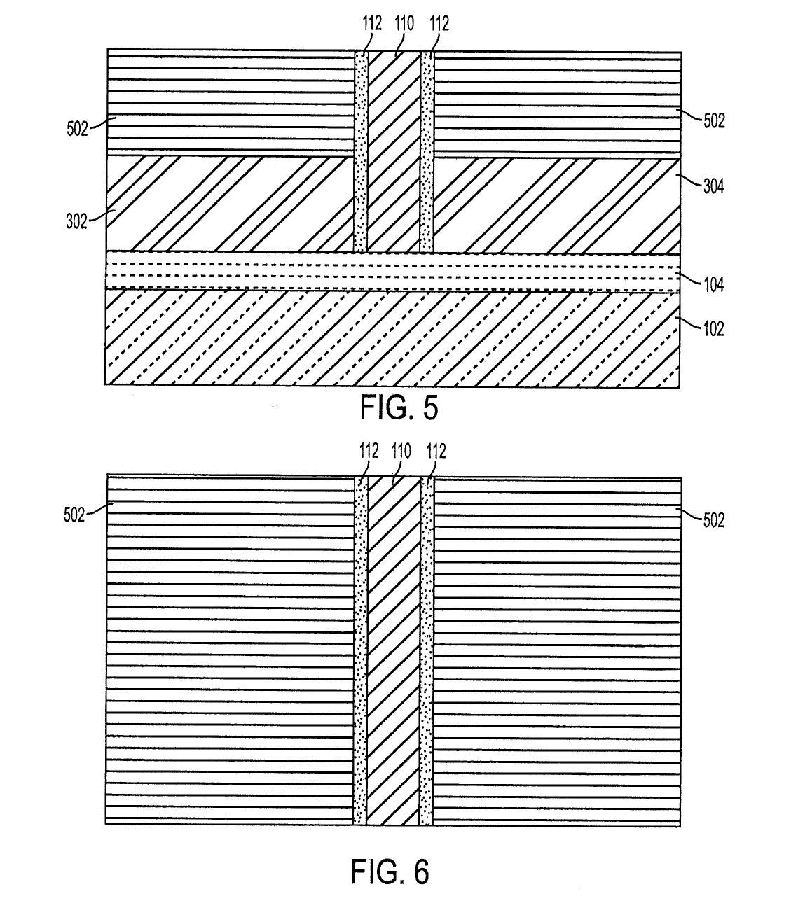

FIG. 5 illustrates a side view, and FIG. 6 illustrates a top view of the resultant structure following the removal of the hardmask layer 108 (of FIG. 3) and the deposition of an insulator layer 502 over the exposed portions of the source and drain regions 302 and 304. In this regard, a layer of dielectric material such as, for example, an oxide material is deposited over exposed portions of the source and drain regions 302 and 304, the spacers 112, and the dummy gate stack 110. A planarization process such as, for example, a chemical mechanical polishing (CMP) process may be performed to remove overburden of the dielectric material from the top portions of the spacers 112 and the dummy gate stack 110.

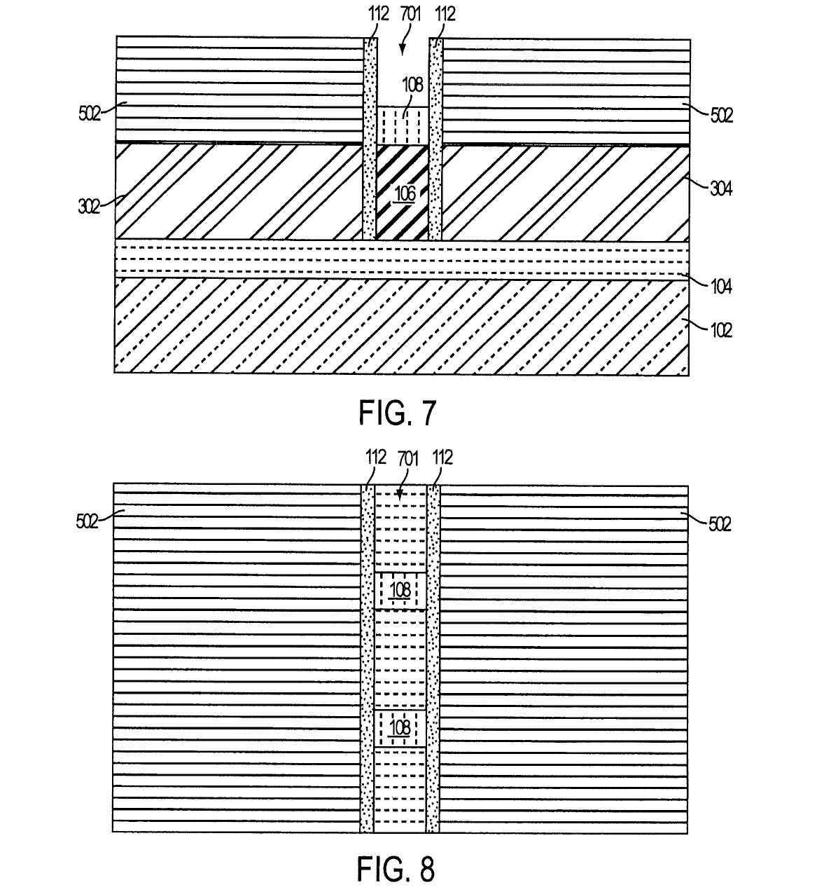

FIG. 7 illustrates a side view, and FIG. 8 illustrates a top view of the resultant structure following the removal of the dummy gate stack 110 (of FIG. 5). The dummy gate stack 110 may be removed by, for example an RIE process that is selective to not appreciably remove exposed portions of the fin 106. In this regard, the hardmask layer 108 may protect portions of the fin 106 in some exemplary methods. The removal of the dummy gate stack 110 forms a cavity 701 defined by exposed portions of the substrate insulator layer 104, the fin 106, the hardmask layer 108, and the spacers 112. The cavity 701 partially defines the channel region of the fin 106.

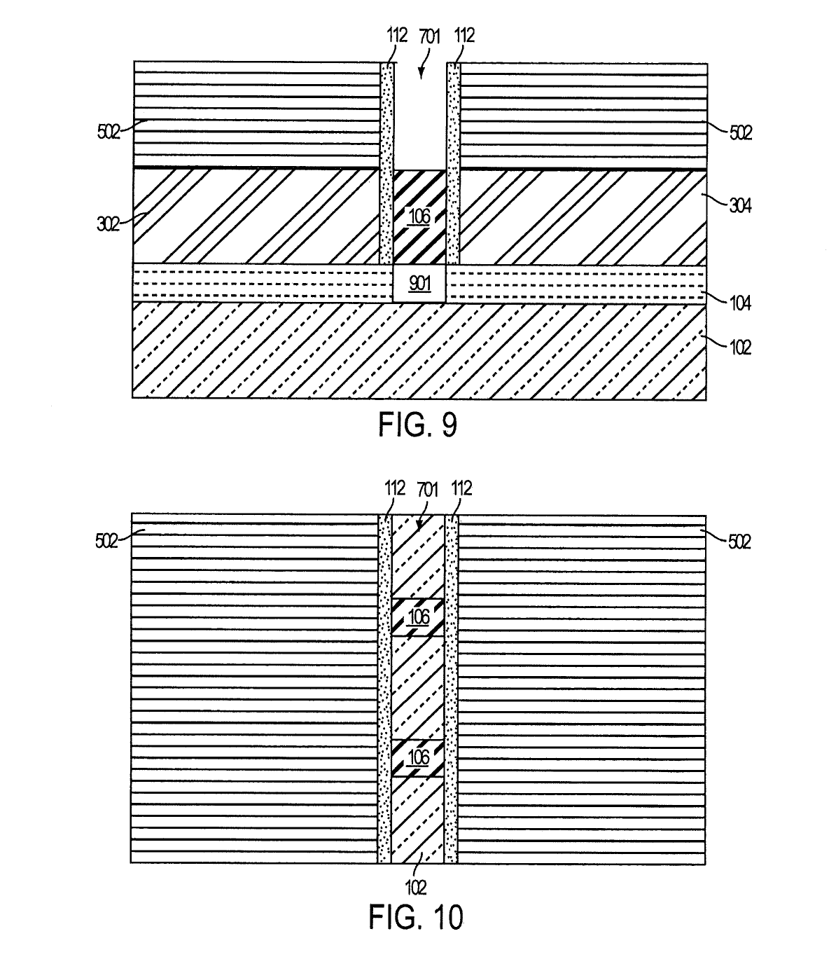

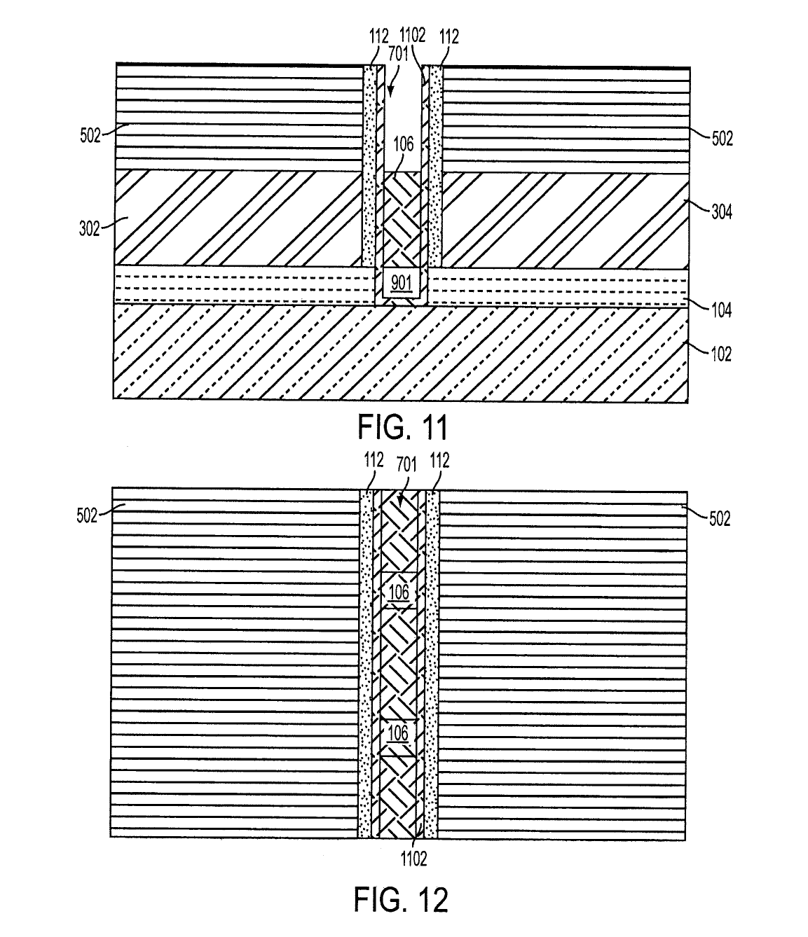

FIG. 9 illustrates a side view, and FIG. 10 illustrates a top view of the resultant structure following the removal of the exposed portions of the hardmask layer 108 and the removal of portions of the substrate insulator layer 104. The removal of portions of the substrate insulator layer 104 results in an increase in the depth of the cavity 701 and the exposure of portions of the substrate 102. The region of the substrate insulator layer 104 that is below the fin 106 is removed to suspend the channel region of the fin 106 above the substrate 102 and form an undercut region 901 below the fin 106. In this regard, an anisotropic etching process such as RIE may be performed to remove portions of the substrate insulator layer 104 that are adjacent to the fin 106 and expose portions of the substrate 102. An isotropic etching process such as, for example, a chemical or wet etching process such as, a diluted hydrofluoric (dHF) etch may be performed to undercut or remove the portion of the substrate insulator layer 104 that is below and disposed under the fin 106 and form the undercut region 901.

FIG. 11 illustrates a side view, and FIG. 12 illustrates a top view of the resultant structure following the deposition of a dielectric layer 1102 conformally over the exposed surfaces in the cavity 701. The dielectric layer 1102 may include a single layer or a plurality of layers of one or more dielectric materials such as, for example, a high-K material.

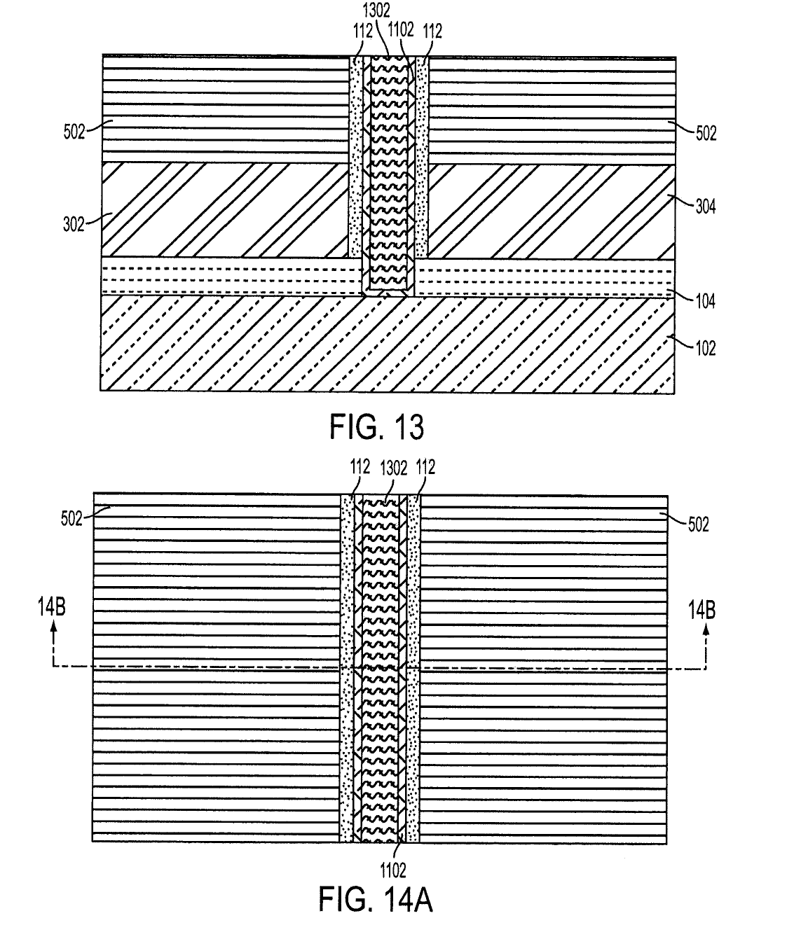

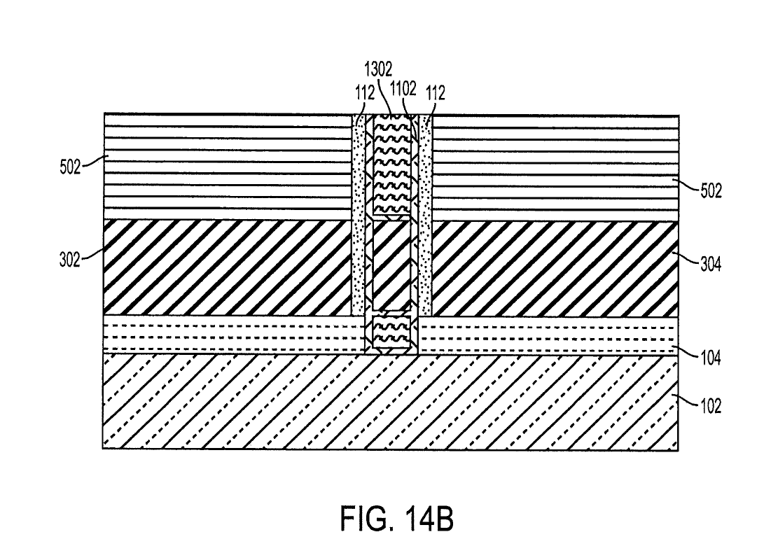

FIG. 13 illustrates a side view, and FIG. 14A illustrates a top view of the resultant structure following the deposition of a gate conductor portion 1302 over the dielectric layer 1102 that fills the cavity 701 including the undercut region 901 (of FIG. 9). FIG. 14B illustrates a cut away view of the structure along the line 14B (of FIG. 14A).

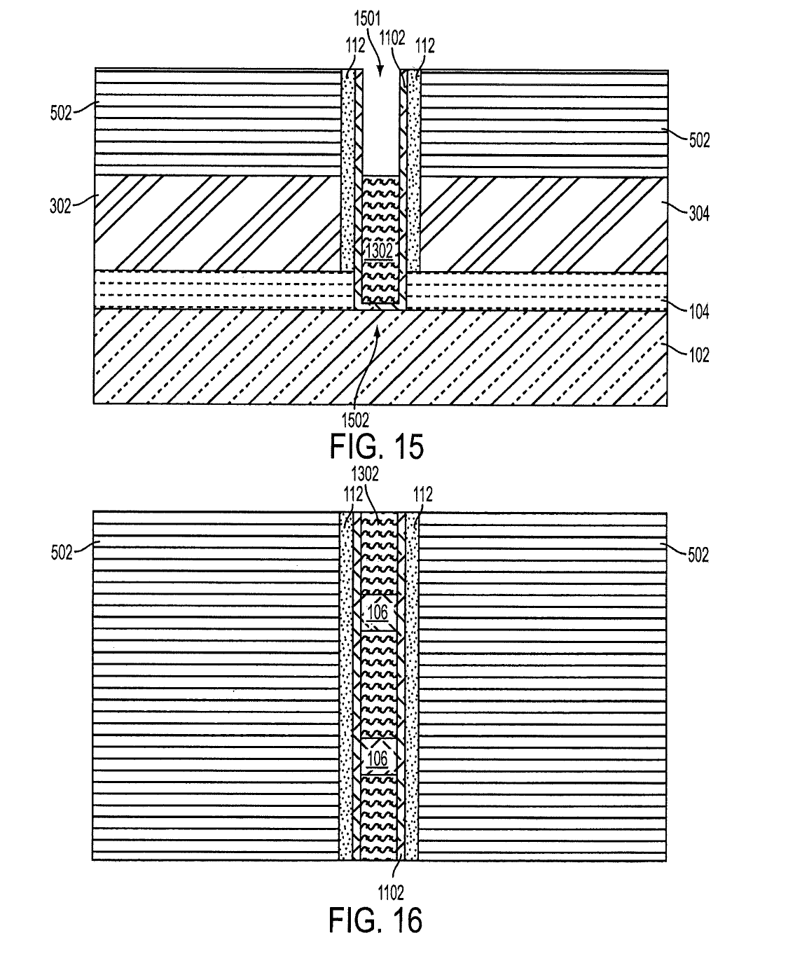

FIG. 15 illustrates a side view, and FIG. 16 illustrates a top view of the resultant structure following the removal of a portion of the gate conductor portion 1302, which forms a cavity 1501 that exposes a portion of the dielectric layer 1102 on the fin 106. The portion of the gate conductor portion 1302 may be removed by, for example, an isotropic etching process that selectively removes the gate conductor portion 1302 material. The removal of the portion of the gate conductor portion 1302 defines a gate stack 1502.

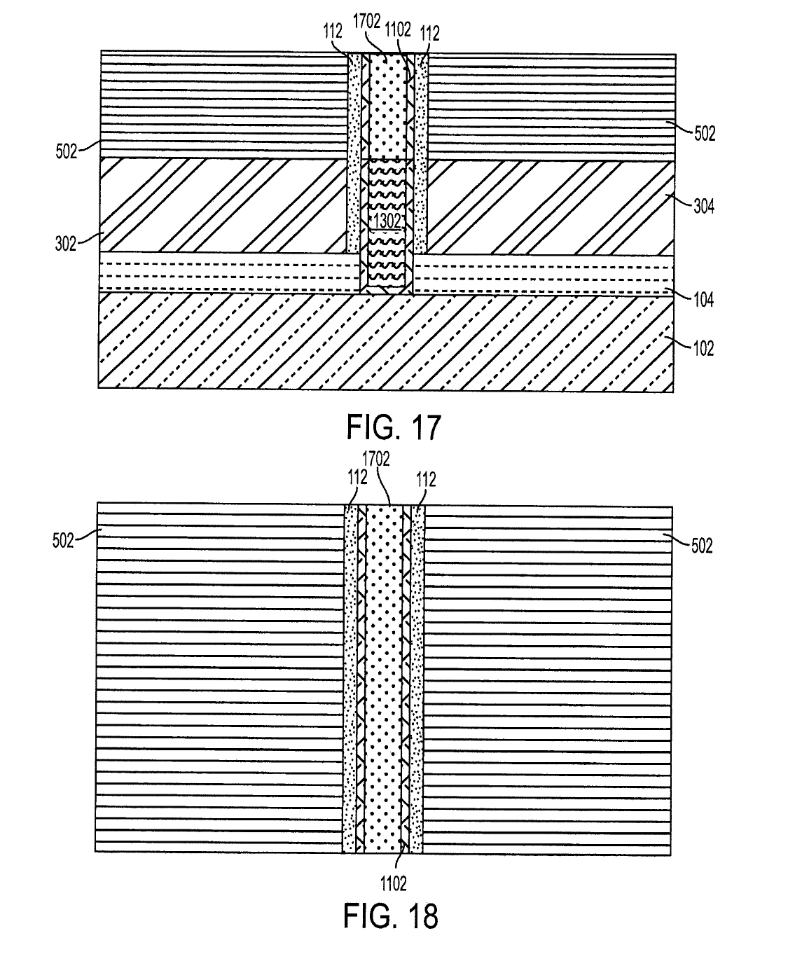

FIG. 17 illustrates a side view, and FIG. 18 illustrates a top view of the resultant structure following the deposition of an insulator portion 1702 such as, for example an oxide or nitride material in the cavity 1501 (of FIG. 15). The insulator portion 1702 may be formed by, for example, the deposition of a layer of insulator material in the cavity 1501 and over the insulator layer 502 followed by a planarization process such as CMP that removes the overburden portions of the insulator material from the insulator layer 502.

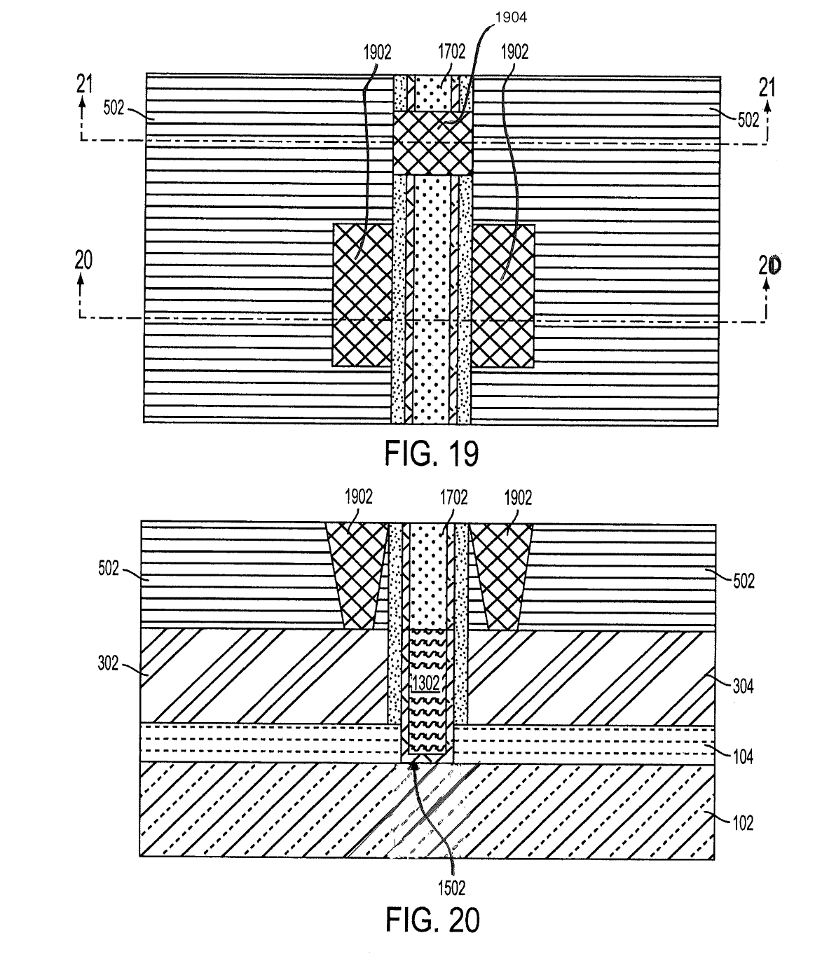

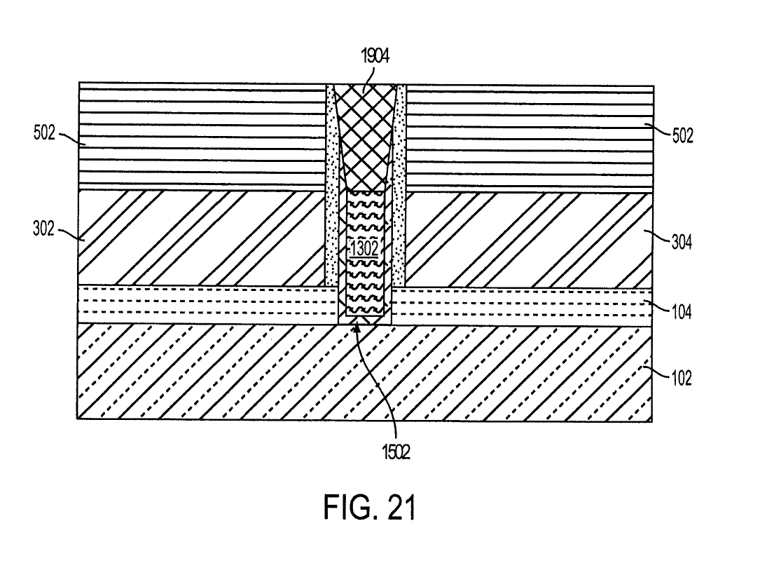

FIG. 19 illustrates a top view, FIG. 20 illustrates a cut away view along the line 20 of FIG. 19, and FIG. 21 illustrates a cut away view along the line 21 of FIG. 19 of the resultant structure following the formation of conductive vias 1902 and 1904. The conductive vias 1902 and 1904 may be formed by, for example, performing a lithographic patterning and etching process that removes portions of the insulator layer 502 to form cavities that expose portions of the source and drain regions 302 and 304 and the gate stack 1502. The cavities are filled by depositing a conductive material layer that fills the cavities. The overburden of the conductive material layer may be removed from the surface of the insulator layer 502 using a planarization process such as CMP.

The embodiments described herein offer a method and resultant structure of a multi-gate FinFET device having reduced parasitic capacitance due to the arrangement of the conductive vias 1902 relative to the gate stack 1502. In this regard, the conductive vias 1902 are arranged above the gate stack 1502, which is inverted with a gate contact extending through the substrate 102. Such an arrangement allows an increase in the pitch scaling of the gate stack 1502 without increasing parasitic capacitance.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1-20. (canceled)

21. A field effect transistor device, comprising:
a substrate;
a substrate insulator layer formed on the substrate;
a semiconductor fin formed on the substrate insulator layer; and
a gate conductor portion wrapped around only side and bottom surfaces of the semiconductor fin, the gate conductor portion filling a recess created by removal of a portion of the substrate insulator layer below the semiconductor fin, wherein a top surface of the gate conductor portion is co-planar with an entire top surface of the semiconductor fin.

22. The field effect transistor device of claim 21, further comprising source and drain regions formed adjacent the side surfaces of the semiconductor fin, the source and drain regions located at opposing sides of the gate conductor portion.

23. The field effect transistor device of claim 22, wherein the source and drain regions comprise epitaxial materials.

24. The field effect transistor device of claim 22, further comprising first and second conductive vias in contact with the source and drain regions, respectively, such that a bottom surface of the first and second conductive vias is substantially co-planar with the top surface of the semiconductor fin and the top surface of the gate conductor portion.

25. The field effect transistor device of claim 24, further comprising a third conductive via in contact with the top surface of the gate conductor portion.

26. The field effect transistor device of claim 21, wherein the recess created by removal of a portion of the substrate insulator layer below the semiconductor fin extends all the way to the top surface of the substrate.
